(19) United States
(12) Patent Application Publication
(10) Pub. No.: US 2023/0387054 A1
(43) Pub. Date: Nov. 30, 2023

(54) SEMICONDUCTOR PACKAGE

(71) Applicant: SAMSUNG ELECTRONICS CO., LTD., Suwon-si (KR)

(72) Inventor: Junyoung KO, Suwon-si (KR)

(73) Assignee: SAMSUNG ELECTRONICS CO., LTD., Suwon-si (KR)

(21) Appl. No.: 18/120,866

(22) Filed: Mar. 13, 2023

(30) Foreign Application Priority Data
May 24, 2022 (KR) 10-2022-0063378

(51) Int. Cl. H01L 23/00

(52) U.S. Cl. CPC H01L 24/06; H01L 24/14; H01L 2224/04042; H01L 2224/02372; H01L 2224/0603; H01L 2224/06169; H01L 2224/1403; H01L 2224/14051; H01L 2224/1416

(57) ABSTRACT

A semiconductor package is provided. The semiconductor package includes a substrate including first and second surfaces opposite to each other, a redistribution layer on the first surface and having third and fourth surfaces opposite to each other wherein the third surface of the redistribution layer faces the first surface, a semiconductor chip between the substrate and the redistribution layer, the semiconductor chip spaced apart from the first surface and electrically connected to the third surface, a connection structure between the substrate and the redistribution layer and horizontally spaced apart from the semiconductor chip wherein the connection structure is electrically connected to the first surface and the third surface, and a dielectric layer between the substrate and the redistribution layer. The dielectric layer covers the semiconductor chip and the connection structure and extends between the semiconductor chip and the first surface.

### CROSS-REFERENCE TO RELATED APPLICATION

This application is based on and claims priority under 35 U.S.C § 119 to Korean Patent Application No. 10-2022-0063378 filed on May 24, 2022 in the Korean Intellectual Property Office, the disclosure of which is hereby incorporated by reference in its entirety.

### BACKGROUND

The disclosure relates to a semiconductor package and a method of fabricating the same, and more particularly, to a semiconductor package including a redistribution layer and a method of fabricating the same.

A semiconductor package is provided to implement an integrated circuit chip to qualify for use in electronic products. Typically, in the semiconductor package, a semiconductor chip is mounted on a printed circuit board (PCB) and bonding wires or bumps are used to electrically connect the semiconductor chip to the printed circuit board. With the recent developments in the electronics industry, various researches have been conducted to improve reliability and durability of semiconductor packages. In addition, to increase in production of semiconductor packages, many studies have been conducted on package technology such as wafer level package and panel level package.

### SUMMARY

According to an aspect of the disclosure, there is provided a semiconductor package capable of simplifying fabrication process and reducing fabrication cost and a method of fabricating the same.

According to an aspect of the disclosure, there is provided a semiconductor package capable of being compatible with wafer-level package process and panel-level package process and a method of fabricating the same.

According to an aspect of the disclosure, there is provided a semiconductor package, including: a substrate having a first surface and a second surface that are opposite to each other; a redistribution layer provided on the first surface of the substrate, the redistribution layer having a third surface and a fourth surface that are opposite to each other, the third surface of the redistribution layer facing the first surface of the substrate; a semiconductor chip provided between the substrate and the redistribution layer, the semiconductor chip being spaced apart from the first surface of the substrate and electrically connected to the third surface of the redistribution layer; a connection structure provided between the substrate and the redistribution layer and horizontally spaced apart from the semiconductor chip, the connection structure being configured to electrically connect the substrate and the redistribution layer; and a first dielectric layer provided between the substrate and the redistribution layer, wherein the semiconductor chip and the connection structure are provided in the first dielectric layer.

According to another aspect of the disclosure, there is provided a semiconductor package including: a substrate including a first surface and a second surface that are opposite to each other; a redistribution layer provided on the first surface of the substrate, the redistribution layer having a third surface and a fourth surface that are opposite to each other, the third surface of the redistribution layer facing the first surface of the substrate; and at least one sub-semiconductor chip provided on the fourth surface of the redistribution layer, wherein the substrate is a printed circuit board, and wherein the substrate includes: a wiring dielectric layer; a plurality of upper wiring patterns in the wiring dielectric layer and adjacent to the first surface of the substrate; a plurality of lower wiring patterns on the wiring dielectric layer and adjacent to the second surface of the substrate; and a mask layer adjacent to the second surface of the substrate and adjacent to the plurality of lower wiring patterns.

According to another aspect of the disclosure, there is provided a semiconductor package, including: a substrate; a redistribution layer provided on the substrate; a dielectric layer provided between the substrate and the redistribution layer, and including: a semiconductor chip; a plurality of connection structures spaced apart from each other, and from the semiconductor chip, the plurality of connection structures being configured to electrically connect the substrate and the redistribution layer.

### BRIEF DESCRIPTION OF THE DRAWINGS

FIG. 1 illustrates a cross-sectional view showing a semiconductor package according to some example embodiments of the disclosure.

FIGS. 2 to 8 illustrate cross-sectional views showing a method of fabricating a semiconductor package according to some example embodiments of the disclosure.

FIG. 9 illustrates a cross-sectional view showing a semiconductor package according to some example embodiments of the disclosure.

FIGS. 10 and 11 illustrate cross-sectional views showing a method of fabricating a semiconductor package according to some example embodiments of the disclosure.

FIG. 12 illustrates a cross-sectional view showing a semiconductor package according to some example embodiments of the disclosure.

FIG. 13 illustrates a cross-sectional view showing a semiconductor package according to some example embodiments of the disclosure.

FIG. 14 illustrates a cross-sectional view showing a semiconductor package according to some example embodiments of the disclosure.

FIGS. 15 to 18 illustrate cross-sectional views showing a method of fabricating a semiconductor package according to some example embodiments of the disclosure.

FIG. 19 illustrates a cross-sectional view showing a semiconductor package according to some example embodiments of the disclosure.

### DETAIL PARTED DESCRIPTION OF EMBODIMENTS

The following will now describe in detail some example embodiments of the disclosure with reference to the accompanying drawings.

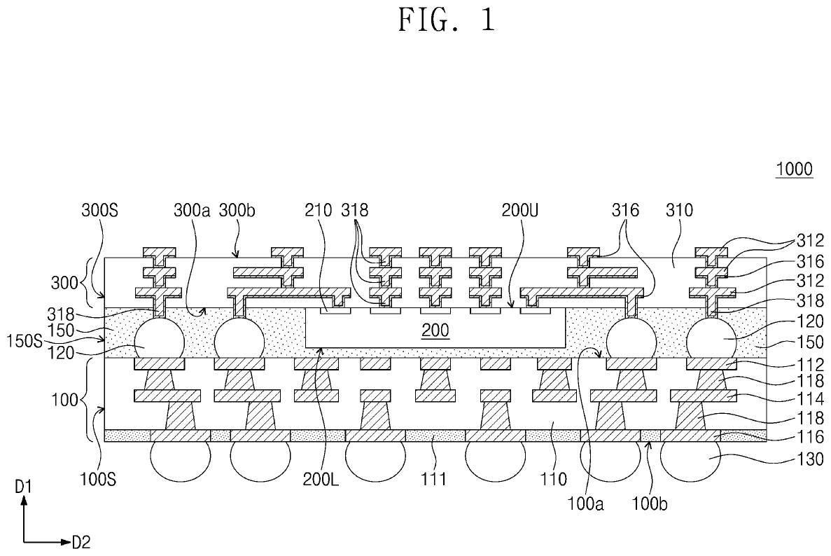

FIG. 1 illustrates a cross-sectional view showing a semiconductor package according to some example embodiments of the disclosure.

Referring to FIG. 1, a semiconductor package 1000 may include a substrate 100, a redistribution layer 300 on the substrate 100, a semiconductor chip 200 between the substrate 100 and the redistribution layer 300, connection structures 120 that are provided between the substrate 100 and the redistribution layer 300 and are horizontally spaced apart from the semiconductor chip 200, and a dielectric layer 150 that is provided between the substrate 100 and the redistribution layer 300 and covers the semiconductor chip 200 and the connection structures 120.

The substrate 100 may have a first surface 100a and a second surface 100b that are opposite to each other, and the redistribution layer 300 may be provided on the first surface 100a of the substrate 100. The substrate 100 may be a printed circuit board, for example, an embedded trace substrate (ETS). The substrate 100 may include a wiring dielectric layer 110, upper wiring patterns 112 buried in the wiring dielectric layer 110 and adjacent to the first surface 100a, lower wiring patterns 116 provided on the wiring dielectric layer 110 and adjacent to the second surface 100b, a mask layer 111 provided on the wiring dielectric layer 110 and adjacent to the second surface 100b while covering the lower wiring patterns 116, and intermediate wiring patterns 114 and via contacts 118 provided in the wiring dielectric layer 110 and electrically connected to the upper and lower wiring patterns 112 and 116. The upper wiring patterns 112, the intermediate wiring patterns 114, and lower wiring patterns 116 may be spaced apart from each other along a first direction D1 perpendicular to the first surface 100a of the substrate 100. The via contacts 118 may be provided between the upper wiring patterns 112 and the intermediate wiring patterns 114 and between the intermediate wiring patterns 114 and the lower wiring patterns 116. The upper wiring patterns 112, the intermediate wiring patterns 114, and the lower wiring patterns 116 may be electrically connected to each other through the via contacts 118. The upper wiring patterns 112 may be adjacent to the first surface 100a of the substrate 100, and may be horizontally spaced apart from each other along a second direction D2 parallel to the first surface 100a of the substrate 100. The lower wiring patterns 116 may be adjacent to the second surface 100b of the substrate 100, and may be horizontally spaced apart from each other along the second direction D2.

The wiring dielectric layer 110 may include a dielectric polymeric material, and the wiring patterns 112, 114, and 116 and the via contacts 118 may include metal. According to an example embodiment, the wiring patterns 112, 114, and 116 and the via contacts 118 may include copper, but the disclosure is not limited thereto, and as such, the wiring patterns 112, 114, and 116 and the via contacts 118 may include other metal material. The mask layer 111 may be a solder mask or a solder resist, and may include a dielectric material.

Lower connection bumps 130 may be provided on the second surface 100b of the substrate 100. The lower connection bumps 130 may be correspondingly provided on and electrically connected to the lower wiring patterns 116. For example, each of the lower connection bumps 130 may correspond to one of the lower writing patterns 116. However, the disclosure is not limited thereto. The lower connection bumps 130 may be horizontally spaced apart from each other along the second direction D2 on the second surface 100b of the substrate 100. The lower connection bumps 130 may include at least one selected from pillars, bumps, and solder balls, and may be formed of a conductive material. The lower connection bumps 130 may be electrically connected to external terminals.

The redistribution layer 300 may have a third surface 300a and a fourth surface 300b that are opposite to each other, and the third surface 300a of the redistribution layer 300 may face the first surface 100a of the substrate 100. The redistribution layer 300 may include a redistribution dielectric layer 310, redistribution patterns 312, redistribution vias 318, and seed patterns 316. The redistribution dielectric layer 310 may include an organic material such as a photo-imagable dielectric (PID) material, and the photo-imagable dielectric (PID) material may include at least one selected from photosensitive polyimide, polybenzoxazole, phenolic polymer, and benzocyclobutene polymer.

The redistribution patterns 312 may be provided in or on the redistribution dielectric layer 310, and may be spaced apart from each other in the first direction D1. According to an example embodiment, some of the redistribution patterns 312 may be provided on the redistribution dielectric layer 310 and on the fourth surface 300b of the redistribution layer 300, and the remaining ones of the redistribution patterns 312 may be provided in the redistribution dielectric layer 310. For example, the some redistribution patterns 312 that are provided on the redistribution dielectric layer 310 and on the fourth surface 300b of the redistribution layer 300 may be referred to as uppermost redistribution patterns 312. The uppermost redistribution patterns 312 may be called redistribution pads, and may be spaced apart from each other horizontally (e.g., in the second direction D2) on the fourth surface 300b of the redistribution layer 300. The redistribution vias 318 may be provided in the redistribution dielectric layer 310, and may be connected to the redistribution patterns 312. Each of the redistribution vias 318 may be connected to a bottom surface of a corresponding one of the redistribution patterns 312, and the redistribution via 318 and its corresponding redistribution pattern 312 may be formed into a single unitary body. For example, each of the redistribution vias 318 and its corresponding redistribution pattern 312 may be in contact with each other with no interface therebetween. The redistribution patterns 312 may be electrically connected to each other through the redistribution vias 318. The seed patterns 316 may be correspondingly provided on bottom surfaces of the redistribution patterns 312, and may extend along lateral and bottom surfaces of the redistribution vias 318. According to an example embodiment, the redistribution patterns 312 and the redistribution vias 318 may include metal, and the seed patterns 316 may include one or more of copper, titanium, and an alloy thereof. According to an example embodiment, the redistribution patterns 312 and the redistribution vias 318 may include copper, but the disclosure is not limited thereto, and as such, the redistribution patterns 312 and the redistribution vias 318 may include other metal material. The seed patterns 316 may serve as barrier layers, and may prevent diffusion of material included in the redistribution patterns 312 and the redistribution vias 318.

The semiconductor chip 200 may be spaced apart vertically (e.g., along the first direction D1) from the first surface 100a of the substrate 100, and may be electrically connected to the third surface 300a of the redistribution layer 300. The semiconductor chip 200 may have a top surface 200U and a bottom surface 200L that are opposite to each other. The top surface 200U of the semiconductor chip 200 may face the third surface 300a of the redistribution layer 300, for example, may contact the third surface 300a of the redistribution layer 300. The bottom surface 200L of the semiconductor chip 200 may face the first surface 100a of the substrate 100, and may be spaced apart vertically (e.g., along the first direction D1) from the first surface 100a of the substrate 100.

The semiconductor chip 200 may include chip pads 210 adjacent to the top surface 200U of the semiconductor chip 200, and the chip pads 210 may include a conductive material. According to an example embodiment, the conductive material may be metal. The chip pads 210 of the semiconductor chip 200 may be electrically connected to lowermost ones of the redistribution vias 318. The chip pads 210 of the semiconductor chip 200 may be connected to corresponding ones of the lowermost redistribution vias 318. The chip pads 210 may be in direct contact with corresponding ones of the seed patterns 316, and the corresponding seed patterns 316 may be in direct contact with the chip pads 210 and the corresponding redistribution vias 318. The semiconductor chip 200 may be electrically connected to the redistribution layer 300 through the chip pads 210 and the lowermost redistribution vias 318.

The semiconductor chip 200 may be, for example, a memory chip, a logic chip, an application processor (AP) chip, or a system-on-chip (SOC). According to some example embodiments, the semiconductor chip 200 may be replaced with a passive element (e.g., capacitor, inductor, or resistor) or an active element (e.g., diode or transistor), and the passive or active element may be electrically connected through the lowermost redistribution vias 318 to the redistribution layer 300.

The connection structures 120 may be horizontally spaced apart from the semiconductor chip 200, and may be electrically connected to the first surface 100a of the substrate 100 and the third surface 300a of the redistribution layer 300. The connection structures 120 may be provided on and electrically connected to corresponding ones of the upper wiring patterns 112 of the substrate 100. The connection structures 120 may be electrically connected to corresponding ones of the lowermost redistribution vias 318 of the redistribution layer 300. Each of the corresponding redistribution vias 318 may penetrate a portion of the dielectric layer 150 to come into electrical connection with a correspond one of the connection structures 120. The connection structures 120 may be in direct contact with corresponding ones of the seed patterns 316, and the corresponding seed patterns 316 may be in direct contact with the connection structures 120 and the corresponding redistribution vias 318. The connection structures 120 may include at least one selected from pillars, bumps, and solder balls, and may be formed of a conductive material.

The dielectric layer 150 may fill a space between the first surface 100a of the substrate 100 and the third surface 300a of the redistribution layer 300, and may cover the semiconductor chip 200 and the connection structures 120. The dielectric layer 150 may extend between the bottom surface 200L of the semiconductor chip 200 and the first surface 100a of the substrate 100. The dielectric layer 150 may include a thermosetting-resin-containing dielectric material, for example, an Ajinomoto build-up film (ABF).

A lateral surface 100S of the substrate 100 may be exposed without being covered with the dielectric layer 150. The lateral surface 100S of the substrate 100 may be aligned along the first direction D1 with a lateral surface 150S of the dielectric layer 150. A lateral surface 300S of the redistribution layer 300 may be aligned along the first direction D1 with the lateral surface 150S of the dielectric layer 150. The lateral surface 100S of the substrate 100, the lateral surface 150S of the dielectric layer 150, and the lateral surface 300S of the redistribution layer 300 may be aligned with each other along the first direction D1. The semiconductor chip 200 may be electrically connected to the substrate 100 through the redistribution layer 300 and the connection structures 120. The bottom surface 200L of the semiconductor chip 200 may not be electrically connected to the first surface 100a of the substrate 100.

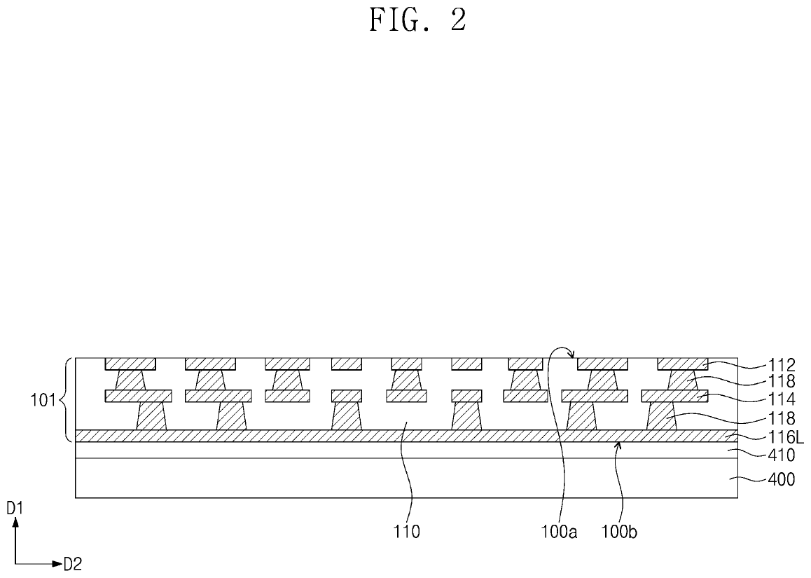

FIGS. 2 to 8 illustrate cross-sectional views showing a method of fabricating a semiconductor package according to some example embodiments of the disclosure. A description repetitive to that of the semiconductor package of FIG. 1 will be omitted for brevity of description.

Referring to FIG. 2, an adhesion layer 410 may be formed on a carrier substrate 400, and a preliminary substrate 101 may be attached to the adhesion layer 410. For example, the carrier substrate 400 may be a glass substrate, and may have a wafer shape or a panel shape. The adhesion layer 410 may include a thermosetting-resin-containing dielectric material, for example, an Ajinomoto build-up film (ABF).

The preliminary substrate 101 may have a first surface 100a and a second surface 100b that are opposite to each other, and the second surface 100b of the preliminary substrate 101 may be attached to the adhesion layer 410. The preliminary substrate 101 may be a printed circuit board, for example, an embedded trace substrate (ETS). The preliminary substrate 101 may have the same shape as that of the carrier substrate 400, and for example, may have a wafer shape or a panel shape.

The preliminary substrate 101 may include a wiring dielectric layer 110, upper wiring patterns 112 buried in the wiring dielectric layer 110 and adjacent to the first surface 100a, a lower conductive layer 116L provided on the wiring dielectric layer 110 and adjacent to the second surface 100b, and intermediate wiring patterns 114 and via contacts 118 provided in the wiring dielectric layer 110 and connected to the upper wiring patterns 112 and the lower conductive layer 116L. The upper wiring patterns 112, the intermediate wiring patterns 114, and the lower conductive layer 116L may be spaced apart from each other in a first direction D1 perpendicular to the first surface 100a of the preliminary substrate 101. The via contacts 118 may be provided between the upper wiring patterns 112 and the intermediate wiring patterns 114 and between the intermediate wiring patterns 114 and the lower conductive layer 116L. The upper wiring patterns 112, the intermediate wiring patterns 114, and the lower conductive layer 116L may be connected to each other through the via contacts 118. The upper wiring patterns 112 may be adjacent to the first surface 100a of the preliminary substrate 101, and may be horizontally spaced apart from each other along a second direction D2 parallel to the first surface 100a. The lower conductive layer 116L may be adjacent to the second surface 100b of the preliminary substrate 101, and may cover an entire surface of the wiring dielectric layer 110 The lower conductive layer 116L may be interposed between the wiring dielectric layer 110 and the adhesion layer 410, and may be attached to the adhesion layer 410.

The wiring dielectric layer 110 may include a dielectric polymeric material, and the upper wiring patterns 112, the intermediate wiring patterns 114, the lower conductive layer 116L, and the via contacts 118 may include metal. According to an example embodiment, the upper wiring patterns 112, the intermediate wiring patterns 114, the lower conductive layer 116L, and the via contacts 118 may include copper, but the disclosure is not limited thereto, and as such, the upper wiring patterns 112, the intermediate wiring patterns 114, the lower conductive layer 116L, and the via contacts 118 may include other metal material.

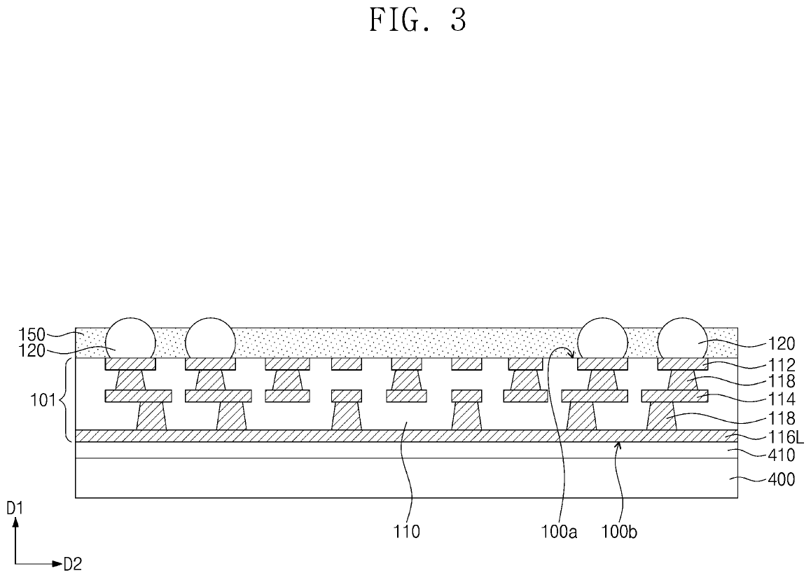

Referring to FIG. 3, connection structures 120 may be formed on the first surface 100a of the preliminary substrate 101 and on corresponding ones of the upper wiring patterns 112. The connection structures 120 may be connected to and in direct contact with the corresponding upper wiring patterns 112.

A dielectric layer 150 may be formed on the first surface 100a of the preliminary substrate 101, covering the connection structures 120. The dielectric layer 150 may include a thermosetting-resin-containing dielectric material. According to an example embodiment, dielectric layer 150 may be an Ajinomoto build-up film (ABF). The dielectric layer 150 may be formed by, for example, a lamination method.

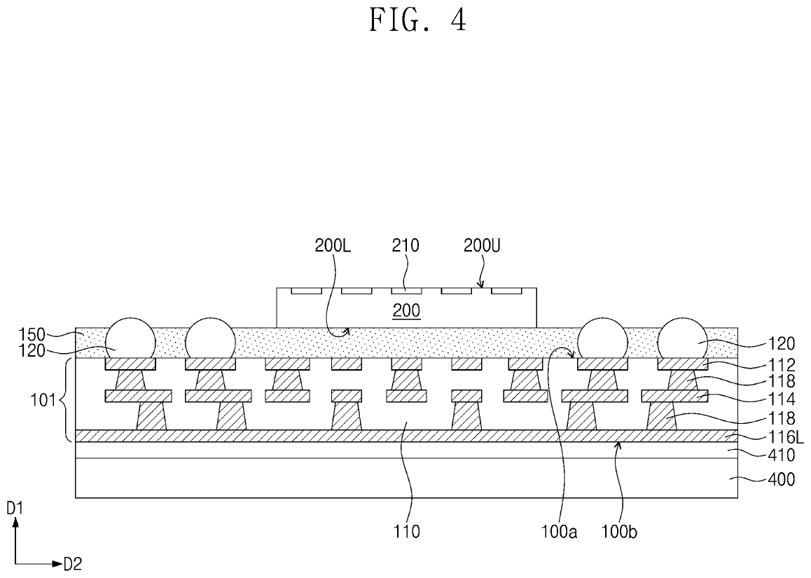

Referring to FIG. 4, a semiconductor chip 200 may be provided on the dielectric layer 150. The semiconductor chip 200 may have a top surface 200U and a bottom surface 200L that are opposite to each other, and the bottom surface 200L of the semiconductor chip 200 may be attached to the dielectric layer 150. The semiconductor chip 200 may include chip pads 210 adjacent to the top surface 200U of the semiconductor chip 200, and the chip pads 210 may include a conductive material. According to an example embodiment, the conduct material may be metal. The semiconductor chip 200 may be, for example, a memory chip, a logic chip, an application processor (AP) chip, or a system-on-chip (SOC). According to some example embodiments, the semiconductor chip 200 may be replaced with a passive element (e.g., capacitor, inductor, or resistor) or an active element (e.g., diode or transistor), and the passive or active element may be provided on the dielectric layer 150.

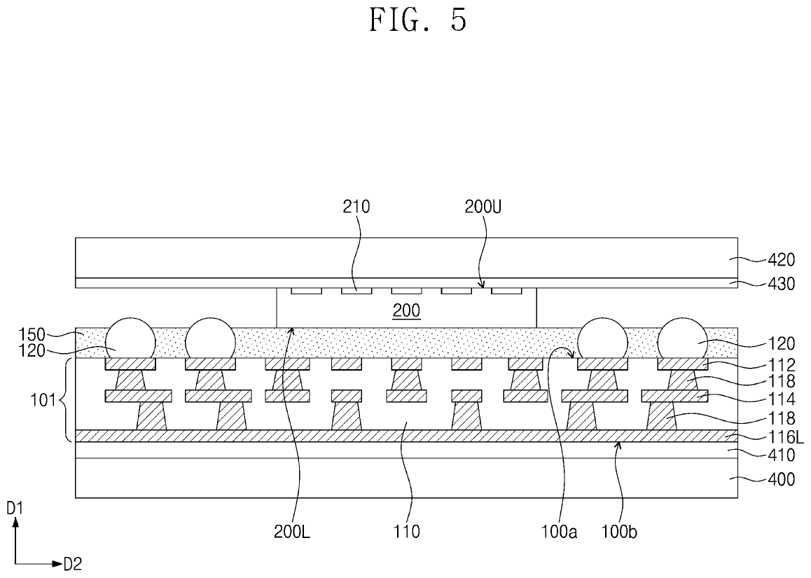

Referring to FIG. 5, a press plate 420 may be provided on the top surface 200U of the semiconductor chip 200. According to an example embodiment, a protection film 430 may be attached to the press plate 420, and the press plate 420 with the protection film 430 may be provided on the top surface 200U of the semiconductor chip 200. The protection film 430 may cover one surface of the press plate 420, and may be provided between the press plate 420 and the semiconductor chip 200. The protection film 430 may be a silicon release film, for example, a film in which a silicon thin film is coated on one or both sides of a polyethylene terephthalate (PET) film.

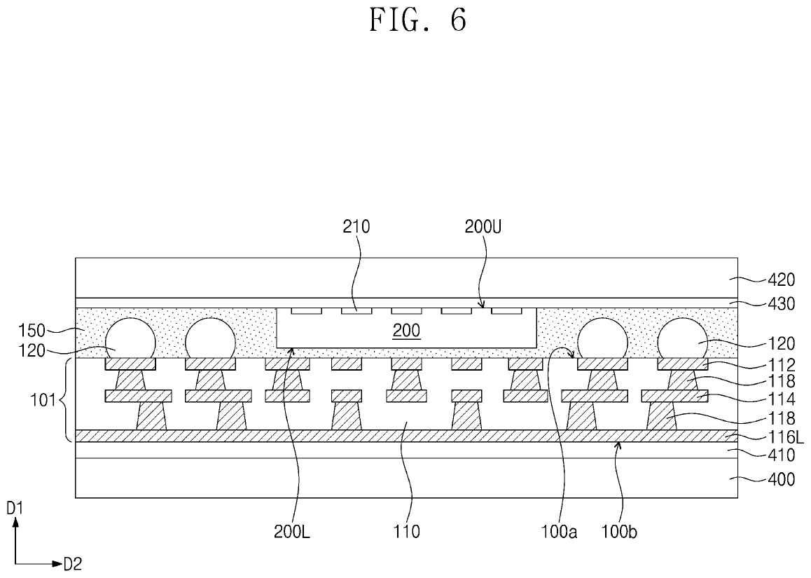

Referring to FIG. 6, a heating process may be performed to allow the dielectric layer 150 to have fluidity, and the semiconductor chip 200 may undergo a pressing process that uses the press plate 420. Therefore, the semiconductor chip 200 may become buried in the dielectric layer 150. As the dielectric layer 150 has fluidity, during the pressing process, the dielectric layer 150 may flow to fill a space between the protection film 430 and the first surface 100a of the preliminary substrate 101 and to cover the semiconductor chip 200 and the connection structures 120. The bottom surface 200L of the semiconductor chip 200 may face the first surface 100a of the preliminary substrate 101, and may be spaced apart vertically (e.g., along the first direction D1) from the first surface 100a of the preliminary substrate 101. The dielectric layer 150 may fill a space between the bottom surface 200L of the semiconductor chip 200 and the first surface 100a of the preliminary substrate 101. According to an example embodiment, the heating process and the pressing process may be performed simultaneously. However, the disclosure is not limited thereto, and as such, the heating process and the pressing process may be performed separately. According to an example embodiment, the heating process and the pressing process may be repeated.

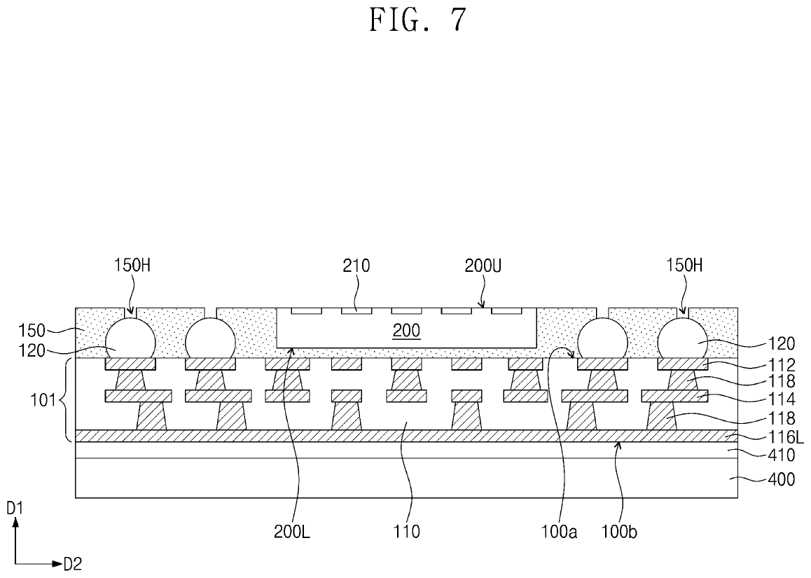

Referring to FIG. 7, after termination of the heating process and the pressing process, the press plate 420 and the protection film 430 may be removed. The removal of the press plate 420 and the protection film 430 may include, for example, physically separating the protection film 430 from the dielectric layer 150 and the semiconductor chip 200. As the press plate 420 and the protection film 430 are removed, the top surface 200U of the semiconductor chip 200 may be exposed and one surface of the dielectric layer 150 may be exposed.

According to an example embodiment, via holes 150H may be formed in the dielectric layer 150 and on corresponding connection structures 120. The via holes 150H may penetrate a portion of the dielectric layer 150, and may correspondingly expose portions of the connection structures 120. The formation of the via holes 150H may include, for example, using a laser process to remove a portion of the dielectric layer 150.

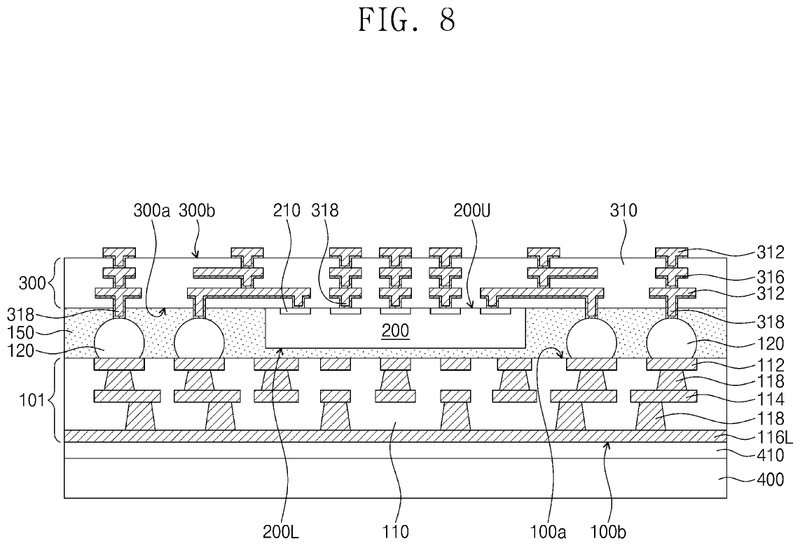

Referring to FIG. 8, a redistribution layer 300 may be formed on the top surface 200U of the semiconductor chip 200 and on the one surface of the dielectric layer 150. The redistribution layer 300 may have a third surface 300a and a fourth surface 300b that are opposite to each other, and the third surface 300a of the redistribution layer 300 may contact the top surface 200U of the semiconductor chip 200 and the one surface of the dielectric layer 150. The redistribution layer 300 may include a redistribution dielectric layer 310, redistribution patterns 312, redistribution vias 318, and seed patterns 316. The redistribution patterns 312 may be formed in or on the redistribution dielectric layer 310, and may be spaced apart from each other in the first direction D1. According to an example embodiment, uppermost ones of the redistribution patterns 312 may be formed on the redistribution dielectric layer 310 and on the fourth surface 300b of the redistribution layer 300, and remaining ones of the redistribution patterns 312 may be formed in the redistribution dielectric layer 310. The uppermost redistribution patterns 312 may be called redistribution pads, and may be spaced apart from each other horizontally (e.g., in the second direction D2) on the fourth surface 300b of the redistribution layer 300. The redistribution vias 318 may be formed in the redistribution dielectric layer 310, and may be connected to bottom surfaces of the redistribution patterns 312. The redistribution vias 318 may be connected to each other through the redistribution patterns 312. The seed patterns 316 may be correspondingly formed on the bottom surfaces of the redistribution patterns 312, may extend along lateral and bottom surfaces of the redistribution vias 318.

The lowermost ones of the redistribution vias 318 may be adjacent to the third surface 300a of the redistribution layer 300, and may be formed to connect to the connection structures 120 and the chip pads 210 of the semiconductor chip 200. According to an example embodiment, some of the lowermost redistribution vias 318 may correspondingly fill the via holes 150H in the dielectric layer 150, and may be correspondingly connected to the connection structures 120. Other ones of the lowermost redistribution vias 318 may be correspondingly connected to the chip pads 210 of the semiconductor chip 200. Lowermost ones of the seed patterns 316 may be adjacent to the third surface 300a of the redistribution layer 300, and may extend along the lateral and bottom surfaces of the lowermost redistribution vias 318. Ones of the lowermost seed patterns 316 may extend into the via holes 150H in the dielectric layer 150, and may correspondingly contact the connection structures 120. Other ones of the lowermost seed patterns 316 may be correspondingly in direct contact with the chip pads 210 of the semiconductor chip 200.

Referring back to FIGS. 1 and 8, after the redistribution layer 300 is formed, the carrier substrate 400 and the adhesion layer 410 may be removed. The removal of the carrier substrate 400 and the adhesion layer 410 may include, for example, using an ablation process to remove the adhesion layer 410. As the carrier substrate 400 and the adhesion layer 410 are removed, the lower conductive layer 116L of the preliminary substrate 101 may be exposed.

The lower conductive layer 116L may be patterned to form lower wiring patterns 116. The lower wiring patterns 116 may horizontally spaced apart from each other along the second direction D2 on the wiring dielectric layer 110. A mask layer 111 may be formed on the wiring dielectric layer 110, covering the lower wiring patterns 116. The mask layer 111 may lie between and expose the lower wiring patterns 116. As the lower wiring patterns 116 and the mask layer 111 are formed, a substrate 100 may be formed. The substrate 100 may have the first surface 100a and the second surface 100b that are opposite to each other.

Lower connection bumps 130 may be formed on the second surface 100b of the substrate 100 and on the lower wiring patterns 116. The lower connection bumps 130 may be horizontally spaced apart from each other along the second direction D2 on the second surface 100b of the substrate 100, and may be electrically connected to the lower wiring patterns 116.

A cutting process may be performed on the substrate 100, the dielectric layer 150, and the redistribution layer 300, and thus a semiconductor package 1000 of FIG. 1 may be fabricated. The cutting process may expose a lateral surface 100S of the substrate 100, a lateral surface 150S of the dielectric layer 150, and a lateral surface 300S of the redistribution layer 300, and the lateral surface 100S, 150S, and 300S may be aligned with each other along the first direction D1.

According to the disclosure, the preliminary substrate 101 having a wafer or panel shape may be formed on the carrier substrate 400 having a wafer or panel shape, and the preliminary substrate 101 may be provided thereon with an upper structure (e.g., the dielectric layer 150, the semiconductor chip 200, the connection structures 120, and the redistribution layer 300). After the upper structure is formed, the lower wiring patterns 116 may be formed by pattering the lower conductive layer 116L of the preliminary substrate 101, and the substrate 100 may be formed by forming the mask layer 111 that covers the lower wiring patterns 116. In this case, a wafer-level package process or a panel-level package process may be available by using the carrier substrate 400 and the preliminary substrate 101 each of which has a wafer shape or a panel shape. In addition, the upper structure may be formed on the preliminary substrate 101 having a wafer shape or a panel shape, and thus it may be possible to simplify a semiconductor package fabrication process.

Accordingly, there may be provided a semiconductor package and its simplified fabrication method compatible with a wafer-level package process and a panel-level package process.

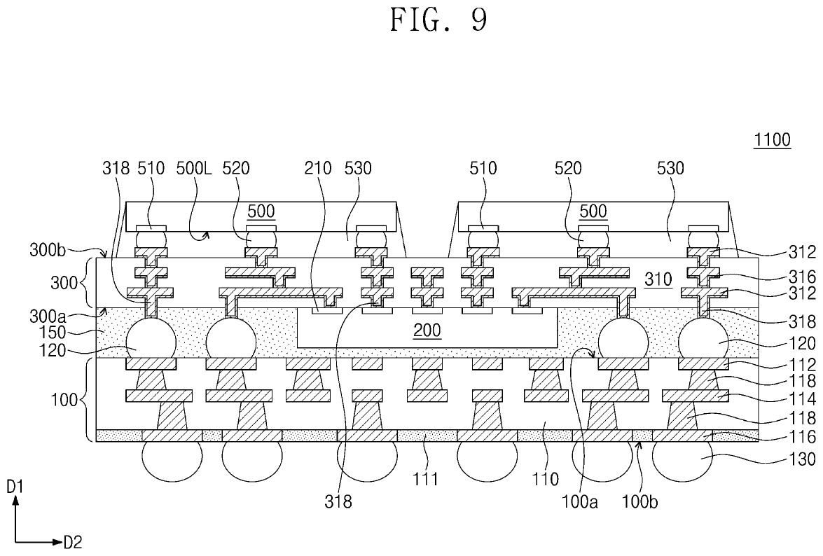

FIG. 9 illustrates a cross-sectional view showing a semiconductor package according to some example embodiments of the disclosure. For brevity of description, the following will focus on a difference from the semiconductor package discussed with reference to FIG. 1.

Referring to FIG. 9, a semiconductor package 1100 may further include at least one first upper semiconductor chip 500 on the redistribution layer 300. The first upper semiconductor chip 500 may be provided in plural on the fourth surface 300b of the redistribution layer 300, and the plurality of first upper semiconductor chips 500 may be spaced apart from each other horizontally (e.g., in the second direction D2) on the fourth surface 300b of the redistribution layer 300.

The first upper semiconductor chip 500 may be electrically connected to the fourth surface 300b of the redistribution layer 300. The first upper semiconductor chip 500 may include first upper chip pads 510 adjacent to a bottom surface 500L of the first upper semiconductor chip 500. The first upper chip pads 510 may include a conductive material (e.g., metal). The bottom surface 500L of the first upper semiconductor chip 500 may face the fourth surface 300b of the redistribution layer 300.

First connection bumps 520 may be correspondingly provided on and electrically connected to the first upper chip pads 510. The first connection bumps 520 may include at least one selected from pillars, bumps, and solder balls, and may be formed of a conductive material. The first connection bumps 520 may be electrically connected to uppermost ones of the redistribution patterns 312 of the redistribution layer 300. Each of the first connection bumps 520 may be provided on a corresponding redistribution pattern 312 of the uppermost redistribution patterns 312, and may be electrically connected to the corresponding redistribution pattern 312. Each of the first connection bumps 520 may be in direct contact with the corresponding redistribution pattern 312. According to some example embodiments, the first connection bumps 520 may be omitted, and in this case, the first upper chip pads 510 may be in direct contact with corresponding redistribution patterns 312 of the uppermost redistribution patterns 312.

A first under-fill layer 530 may be interposed between the bottom surface 500L of the first upper semiconductor chip 500 and the fourth surface 300b of the redistribution layer 300, and may cover the first connection bumps 520. The first under-fill layer 530 may include a dielectric polymeric material, such as an epoxy resin.

The first upper semiconductor chip 500 may be electrically connected to the redistribution layer 300 through the first upper chip pads 510, the first connection bumps 520, and the uppermost redistribution patterns 312, and the semiconductor chip 200 may be electrically connected to the redistribution layer 300 through the chip pads 210 and the lowermost redistribution vias 318. The first upper semiconductor chip 500 and the semiconductor chip 200 may share the redistribution layer 300.

The first upper semiconductor chip 500 may be, for example, a memory chip, a logic chip, an application processor (AP) chip, or a system-on-chip (SOC). According to some example embodiments, the first upper semiconductor chip 500 may be replaced with a passive element (e.g., capacitor, inductor, or resistor) or an active element (e.g., diode or transistor), and the passive or active element may be electrically connected through the uppermost redistribution patterns 312 to the redistribution layer 300.

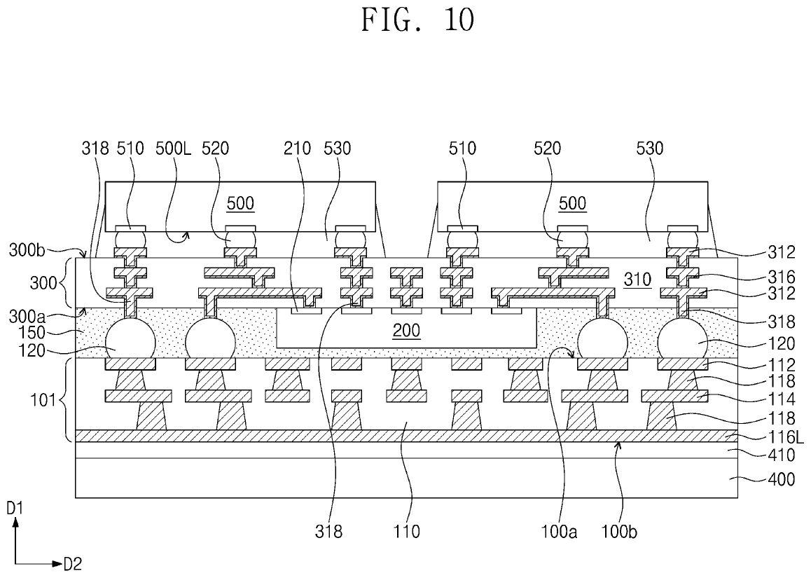

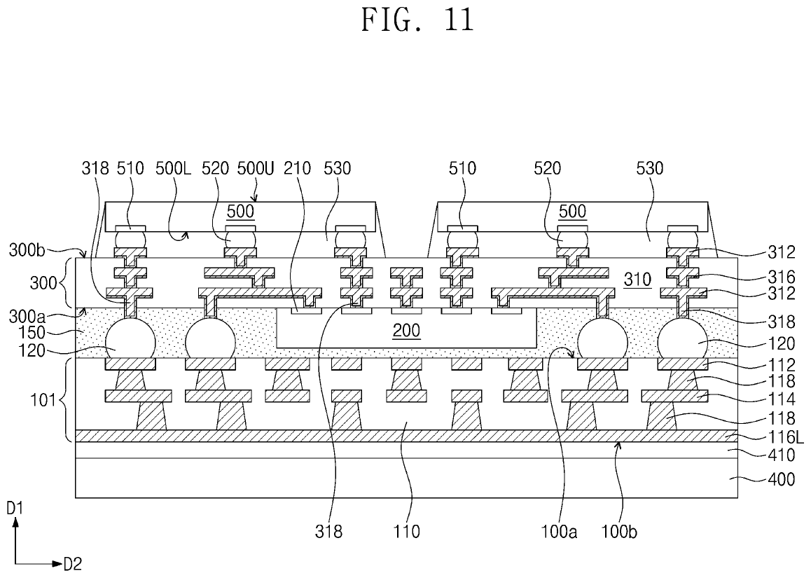

FIGS. 10 and 11 illustrate cross-sectional views showing a method of fabricating a semiconductor package according to some example embodiments of the disclosure. For brevity of description, the following will focus on differences from the method of fabricating a semiconductor package discussed with reference to FIGS. 2 to 8.

As discussed with reference to FIGS. 2 to 8, the adhesion layer 410 may be formed on the carrier substrate 400, and the preliminary substrate 101 may be attached to the adhesion layer 410. The connection structures 120 and the dielectric layer 150 may be formed on the preliminary substrate 101, and the semiconductor chip 200 may be buried in the dielectric layer 150. The redistribution layer 300 may be formed on the dielectric layer 150 and the semiconductor chip 200.

Referring to FIG. 10, at least one first upper semiconductor chip 500 may be mounted on the fourth surface 300b of the redistribution layer 300. The first upper semiconductor chip 500 may include first upper chip pads 510 adjacent to a bottom surface 500L of the first upper semiconductor chip 500, and first connection bumps 520 may be correspondingly provided on the first upper chip pads 510. The first upper semiconductor chip 500 may be provided to allow its bottom surface 500L to face the fourth surface 300b of the redistribution layer 300, and the first connection bumps 520 may be connected to uppermost ones of the redistribution patterns 312 of the redistribution layer 300.

A first under-fill layer 530 may be formed between the bottom surface 500L of the first upper semiconductor chip 500 and the fourth surface 300b of the redistribution layer 300, and may cover the first connection bumps 520.

Referring to FIG. 11, a grinding process may be performed on a top surface 500U of the first upper semiconductor chip 500, and therefore, the first upper semiconductor chip 500 may have a reduced thickness (e.g., in the first direction DO.

Referring back to FIGS. 9 and 11, after the grinding process, the carrier substrate 400 and the adhesion layer 410 may be removed. As the carrier substrate 400 and the adhesion layer 410 are removed, the lower conductive layer 116L of the preliminary substrate 101 may be exposed. Afterwards, as discussed with reference to FIGS. 1 and 8, the lower conductive layer 116L may be patterned to form lower wiring patterns 116, and a mask layer 111 may be formed on the wiring dielectric layer 110 so as to cover the lower wiring patterns 116. As the lower wiring patterns 116 and the mask layer 111 are formed, a substrate 100 may be formed. Lower connection bumps 130 may be correspondingly formed on the lower wiring patterns 116. A cutting process may be performed on the substrate 100, the dielectric layer 150, and the redistribution layer 300, and thus a semiconductor package 1100 of FIG. 9 may be fabricated.

According to some example embodiments, the first upper semiconductor chip 500 and the semiconductor chip 200 may share the redistribution layer 300, and therefore, it may not be required to an additional redistribution layer. Accordingly, there may be provided a semiconductor package and a method of fabricating the same whose fabrication cost is reduced.

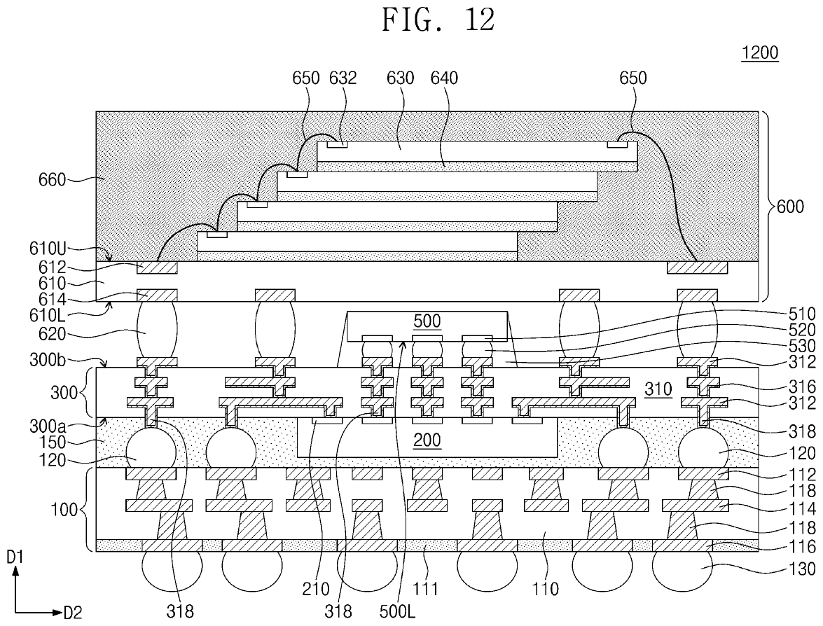

FIG. 12 illustrates a cross-sectional view showing a semiconductor package according to some example embodiments of the disclosure. For brevity of description, the following will focus on a difference from the semiconductor package discussed with reference to FIG. 1.

Referring to FIG. 12, a semiconductor package 1200 may further include at least one first upper semiconductor chip 500 on the redistribution layer 300 and an upper semiconductor package 600 on the first upper semiconductor chip 500. The first upper semiconductor chip 500 and the upper semiconductor package 600 may be electrically connected to the fourth surface 300b of the redistribution layer 300.

The first upper semiconductor chip 500 may be substantially the same as the first upper semiconductor chip 500 discussed with reference to FIG. 9. The first upper semiconductor chip 500 may include first upper chip pads 510 adjacent to a bottom surface 500L of the first upper semiconductor chip 500, and the bottom surface 500L of the first upper semiconductor chip 500 may face the fourth surface 300b of the redistribution layer 300. First connection bumps 520 may be correspondingly provided on and electrically connected to the first upper chip pads 510. The first connection bumps 520 may be electrically connected to corresponding redistribution patterns 312 of the uppermost redistribution patterns 312. According to some example embodiments, the first connection bumps 520 may be omitted, and in this case, the first upper chip pads 510 may be in direct contact with corresponding redistribution patterns 312 of the uppermost redistribution patterns 312. A first under-fill layer 530 may be interposed between the bottom surface 500L of the first upper semiconductor chip 500 and the fourth surface 300b of the redistribution layer 300, and may cover the first connection bumps 520. The first upper semiconductor chip 500 may be electrically connected to the redistribution layer 300 through the first upper chip pads 510, the first connection bumps 520, and the uppermost redistribution patterns 312.

The upper semiconductor package 600 may include an upper substrate 610, a plurality of second upper semiconductor chips 630 stacked on the upper substrate 610, and an upper mold layer 660 that is provided on the upper substrate 610 and covers the plurality of second upper semiconductor chips 630.

The upper substrate 610 may include first upper substrate pads 612 adjacent to a top surface 610U of the upper substrate 610 and second upper substrate pads 614 adjacent to a bottom surface 610L of the upper substrate 610. The first and second upper substrate pads 612 and 614 may be electrically connected to each other through internal lines in the upper substrate 610. The upper substrate 610 may be, for example, a printed circuit board. The bottom surface 610L of the upper substrate 610 may face the fourth surface 300b of the redistribution layer 300.

Second connection bumps 620 may be correspondingly provided on and electrically connected to the second upper substrate pads 614 of the upper substrate 610. The second connection bumps 620 may be correspondingly provided on corresponding redistribution patterns 312 of the uppermost redistribution patterns 312, and may be electrically connected to the corresponding redistribution patterns 312. The upper substrate 610 may be electrically connected to the redistribution layer 300 through the second upper substrate pads 614, the second connection bumps 620, and the corresponding redistribution patterns 312.

The plurality of second upper semiconductor chip 630 may be stacked vertically (e.g., in the first direction D1) perpendicular to the top surface 610U of the upper substrate 610. According to some example embodiments of the disclosure, the plurality of second upper semiconductor chips 630 may be stacked to have a stepwise structure. According to some example embodiments, differently from that shown in FIG. 12, the plurality of second upper semiconductor chips 630 may be stacked horizontally (e.g., along the second direction D2) on the top surface 610U of the upper substrate 610. Each of the plurality of second upper semiconductor chip 630 may be, for example, a memory chip, a logic chip, an application processor (AP) chip, or a system-on-chip (SOC). According to some example embodiments, each of the plurality of second upper semiconductor chips 630 may be replaced with a passive element (e.g., capacitor, inductor, or resistor) or an active element (e.g., diode or transistor), and the passive or active element may be stacked vertically or horizontally on the top surface 610U of the upper substrate 610.

According to some example embodiments, the upper semiconductor package 600 may further include a plurality of upper adhesion layers 640 between the plurality of second upper semiconductor chips 630. The plurality of upper adhesion layers 640 may be interposed between the upper substrate 610 and a lowermost one of the plurality of second upper semiconductor chips 630 and between the plurality of second upper semiconductor chips 630. The plurality of upper adhesion layers 640 may include, for example, a dielectric polymeric material, such as an epoxy.

According to some example embodiments, the upper semiconductor package 600 may further include conductive wires 650 that electrically connect the upper substrate 610 to the plurality of second upper semiconductor chips 630. Each of the plurality of second upper semiconductor chips 630 may include a second upper chip pad 632, and the conductive wires 650 may be connected to the second upper chip pads 632 of the plurality of second upper semiconductor chips 630 and to the first upper substrate pads 612 of the upper substrate 610. The plurality of second upper semiconductor chips 630 may be electrically connected through the conductive wires 650 to the upper substrate 610.

The upper mold layer 660 may be provided on the top surface 610U of the upper substrate 610, and may cover the plurality of second upper semiconductor chips 630, the plurality of upper adhesion layers 640, and the conductive wires 650. The upper mold layer 660 may include a dielectric material, such as an epoxy molding compound.

The upper semiconductor package 600 may be electrically connected to the redistribution layer 300 through the second connection bumps 620 and the uppermost redistribution patterns 312, and the first upper semiconductor chip 500 may be electrically connected to the redistribution layer 300 through the first connection bumps 520 and the uppermost redistribution patterns 312. In addition, as discussed with reference to FIG. 1, the semiconductor chip 200 may be electrically connected to the redistribution layer 300 through the chip pads 210 and the lowermost redistribution vias 318. The redistribution layer 300 may be shared by the upper semiconductor package 600, the first upper semiconductor chip 500, and the semiconductor chip 200.

According to the present embodiment, the redistribution layer 300 may be shared by the upper semiconductor package 600, the first upper semiconductor chip 500, and the semiconductor chip 200, and therefore, it may not be required to form an additional redistribution layer 300. Accordingly, there may be provided a semiconductor package and a method of fabricating the same whose fabrication cost is reduced.

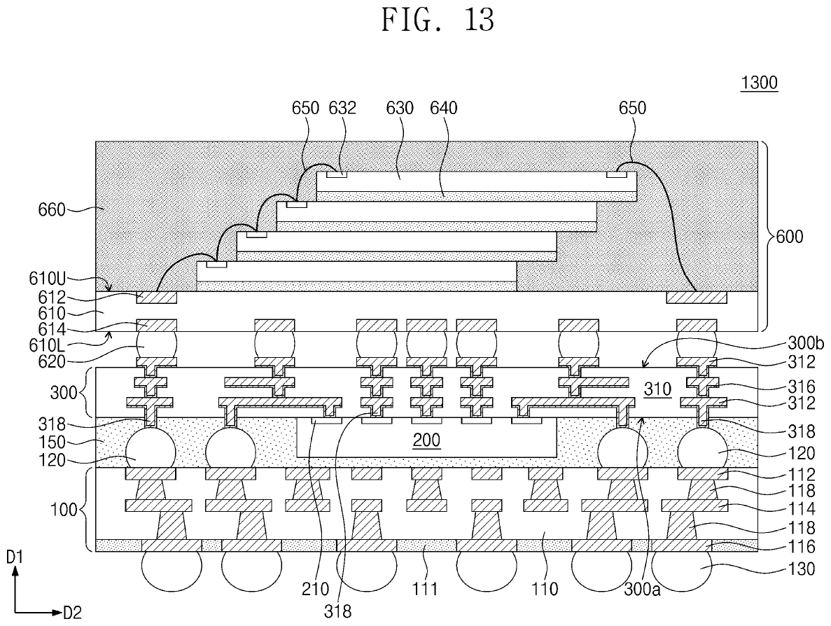

FIG. 13 illustrates a cross-sectional view showing a semiconductor package according to some example embodiments of the disclosure. For brevity of description, the following will focus on a difference from the semiconductor package discussed with reference to FIG. 1.

Referring to FIG. 13, a semiconductor package 1300 may further include an upper semiconductor package 600 on the redistribution layer 300. The upper semiconductor package 600 may be electrically connected to the redistribution layer 300. The upper semiconductor package 600 may be substantially the same as the upper semiconductor package 600 discussed with reference to FIG. 12. The semiconductor package 1300 may be substantially the same as the semiconductor package 1200 discussed with reference to FIG. 12, except the first upper semiconductor chip 500 of FIG. 12 is omitted. The upper semiconductor package 600 and the semiconductor chip 200 may share the redistribution layer 300.

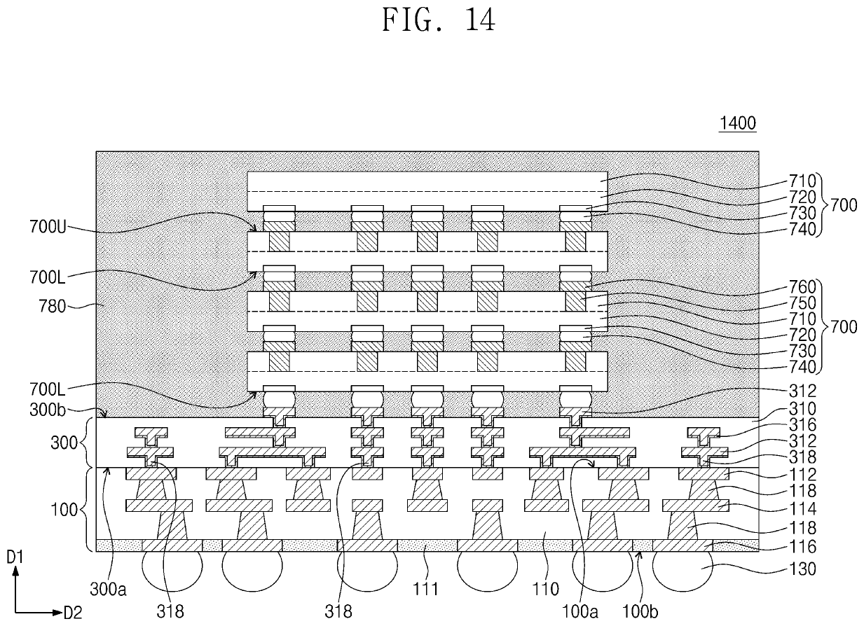

FIG. 14 illustrates a cross-sectional view showing a semiconductor package according to some example embodiments of the disclosure. For brevity of description, the following will focus on a difference from the semiconductor package discussed with reference to FIG. 1.

Referring to FIG. 14, a semiconductor package 1400 may include a substrate 100, a redistribution layer 300 on the substrate 100, and a plurality of sub-semiconductor chips 700 stacked on the redistribution layer 300. The substrate 100 and the redistribution layer 300 may be substantially the same as the substrate 100 and the redistribution layer 300 discussed with reference to FIG. 1. According to some example embodiments, the first surface 100a of the substrate 100 may be in contact with the third surface 300a of the redistribution layer 300. The lowermost redistribution vias 318 of the redistribution layer 300 may be connected to the upper wiring patterns 112 of the substrate 100. The upper wiring patterns 112 may be in direct contact with the lowermost seed patterns 316 of the redistribution layer 300, and the lowermost seed patterns 316 may be in direct contact with the lowermost redistribution vias 318. The wiring dielectric layer 110 of the substrate 100 may be in direct contact with the redistribution dielectric layer 310 of the redistribution layer 300.

The plurality of sub-semiconductor chips 700 may be stacked (e.g., along the third direction D3) on the fourth surface 300b of the redistribution layer 300. Each of the plurality of sub-semiconductor chips 700 may include a semiconductor substrate 710, circuit layer 720 on the semiconductor substrate 710, sub-chip pads 730, sub-connection bumps 740 on the sub-chip pads 730, chip through electrodes 750 that penetrate the semiconductor substrate 710, and electrode pads 760 on the chip through electrodes 750. The semiconductor substrate 710 may include, for example, one or more of a silicon substrate, a germanium substrate, and a silicon-germanium substrate. The circuit layer 720 and the sub-chip pads 730 may be adjacent to a bottom surface 700L of each of the sub-semiconductor chips 700, and the circuit layer 720 may be provided between the semiconductor substrate 710 and the sub-chip pads 730. The circuit layer 720 may include an integrated circuit, and the sub-chip pads 730 may be electrically connected to the circuit layer 720. The sub-chip pads 730 may include metal (e.g., copper). The sub-connection bumps 740 may be correspondingly provided on and electrically connected to the sub-chip pads 730. The sub-connection bumps 740 may include at least one of pillars, bumps, and solder balls, and may be formed of a conductive material. The chip through electrodes 750 may penetrate the semiconductor substrate 710 to come into electrical connection with the circuit layer 720. The electrodes pads 760 may be correspondingly provided on top surfaces 700U of the plurality of sub-semiconductor chips 700, and may be electrically connected to the chip through electrodes 750. The chip through electrode 750 and the electrode pads 760 may include metal (e.g., copper).

The bottom surface 700L of a lowermost one of the plurality of sub-semiconductor chips 700 may face the fourth surface 300b of the redistribution layer 300. The bottom surfaces 700L of remaining ones of the plurality of sub-semiconductor chips 700 may face the top surfaces 700U of the sub-semiconductor chips 700 that underlie the remaining sub-semiconductor chips 700. The sub-connection bumps 740 of the lowermost sub-semiconductor chip 700 may be electrically connected to the uppermost redistribution patterns 312 of the redistribution layer 300. The sub-connection bumps 740 of remaining ones of the plurality of sub-semiconductor chips 700 may be electrically connected to the electrode pads 760 of the sub-semiconductor chips 700 that underlies the remaining sub-semiconductor chips 700. An uppermost one of the plurality of sub-semiconductor chips 700 may include neither the chip through electrodes 750 nor the electrode pads 760. The plurality of sub-semiconductor chips 700 may be electrically connected to each other through the sub-connection bumps 740, the electrode pads 760, and the chip through electrodes 750, and may be electrically connected through the uppermost redistribution patterns 312 to the redistribution layer 300.

The semiconductor package 1400 may further include a mold layer 780 that is provided on the fourth surface 300b and covers the plurality of sub-semiconductor chips 700. The mold layer 780 may extend between the plurality of sub-semiconductor chips 700 and between the lowermost sub-semiconductor chip 700 and the redistribution layer 300, and may cover the sub-connection bumps 740. The mold layer 780 may include a dielectric material, such as an epoxy molding compound.

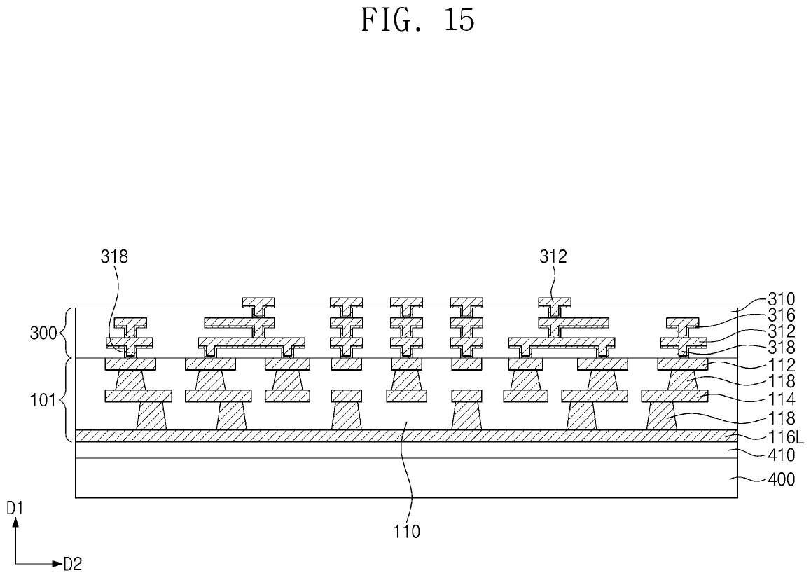

FIGS. 15 to 18 illustrate cross-sectional views showing a method of fabricating a semiconductor package according to some example embodiments of the disclosure. For brevity of description, the following will focus on differences from the method of fabricating a semiconductor package discussed with reference to FIGS. 2 to 8.

Referring to FIG. 15, an adhesion layer 410 may be formed on a carrier substrate 400, and a preliminary substrate 101 may be attached to the adhesion layer 410. For example, the carrier substrate 400 may be a glass substrate, and may have a wafer shape or a panel shape. The preliminary substrate 101 may be a printed circuit board, for example, an embedded trace substrate (ETS). The preliminary substrate 101 may have the same shape as that of the carrier substrate 400, and may have a wafer shape or a panel shape. A redistribution layer 300 may be formed on the preliminary substrate 101. The redistribution layer 300 may include a redistribution dielectric layer 310, redistribution patterns 312, redistribution vias 318, and seed patterns 316. The carrier substrate 400, the preliminary substrate 101, and the redistribution layer 300 may be substantially the same as the carrier substrate 400, the preliminary substrate 101, and the redistribution layer 300 that are discussed with reference to FIGS. 2 to 8.

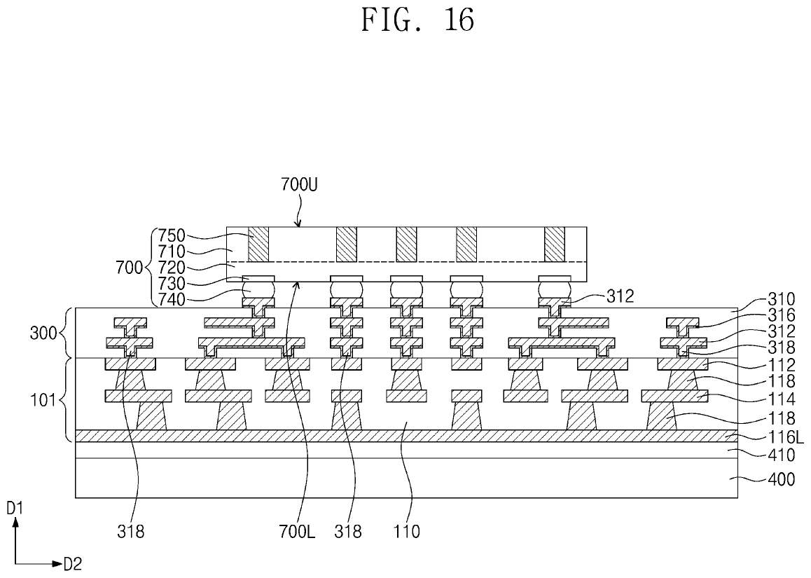

Referring to FIG. 16, a sub-semiconductor chip 700 may be mounted on the redistribution layer 300. The sub-semiconductor chip 700 may include a semiconductor substrate 710, a circuit layer 720 on the semiconductor substrate 710, sub-chip pads 730, sub-connection bumps 740 on the sub-chip pads 730, and chip through electrodes 750 that penetrate the semiconductor substrate 710. The semiconductor substrate 710 may include, for example, one or more of a silicon substrate, a germanium substrate, and a silicon-germanium substrate. The circuit layer 720 and the sub-chip pads 730 may be adjacent to a bottom surface 700L of the sub-semiconductor chip 700, and the circuit layer 720 may be provided between the semiconductor substrate 710 and the sub-chip pads 730. The circuit layer 720 may include an integrated circuit, and the sub-chip pads 730 may be electrically connected to the circuit layer 720. The sub-connection bumps 740 may be correspondingly formed on and electrically connected to the sub-chip pads 730. The chip through electrodes 750 may penetrate the semiconductor substrate 710 to come into electrical connection with the circuit layer 720. The sub-connection bumps 740 may be provided on uppermost ones of the redistribution patterns 312 of the redistribution layer 300, and may be connected to the uppermost redistribution patterns 312.

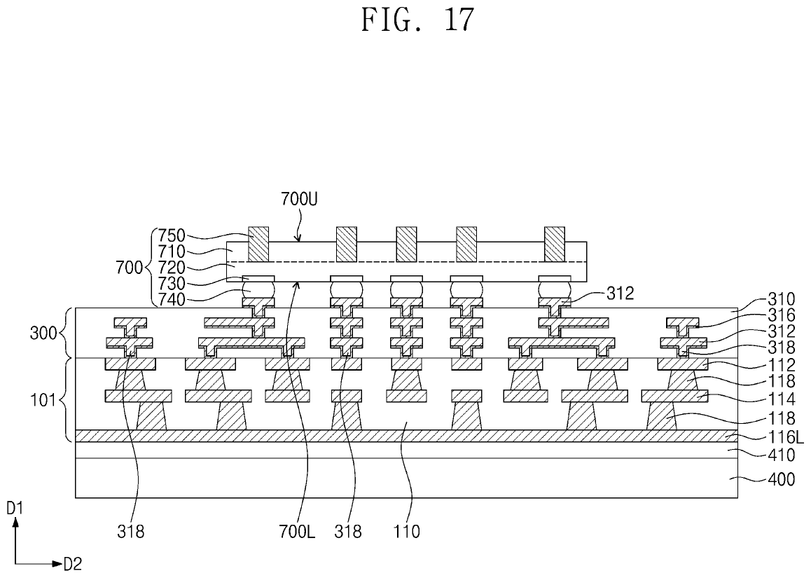

Referring to FIG. 17, a grinding process may be performed on a top surface 700U of the sub-semiconductor chip 700, and thus upper portions of the chip through electrodes 750 may upwardly protrude from the top surface 700U of the sub-semiconductor chip 700.

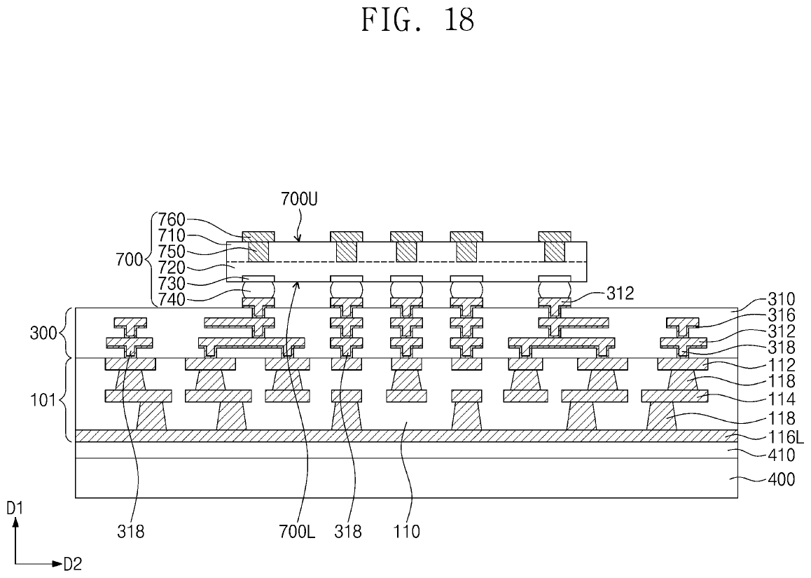

Referring to FIG. 18, electrode pads 760 may be formed on the top surface 700U of the sub-semiconductor chip 700, and may be correspondingly connected to the chip through electrodes 750. The electrode pads 760 may correspond to the protruding upper portions of the chip through electrodes 750.

Referring back to FIGS. 14 and 18, additional sub-semiconductor chips 700 may be stacked vertically (e.g., along the first direction D1) on the sub-semiconductor chip 700. Each of the additional sub-semiconductor chips 700 may be formed by substantially the same method used for forming the sub-semiconductor chip 700. For example, a grinding process may be performed on the top surface 700U of each of the plurality of sub-semiconductor chips 700, and thus upper portions of chip through electrodes 750 of each additional sub-semiconductor chip 700 may upwardly protrude from a top surface 700U of the each additional sub-semiconductor chip 700, and electrode pads 760 may be correspondingly protrude from the protruding upper portions of the chip through electrodes 750. The sub-semiconductor chip 700 and the additional sub-semiconductor chips 700 may be called a plurality of sub-semiconductor chips 700. The plurality of sub-semiconductor chips 700 may be electrically connected to each other through the chip through electrodes 750 and the sub-connection bumps 740, and may be electrically connected to the redistribution layer 300 through the uppermost redistribution patterns 312 of the redistribution layer 300.

A mold layer 780 may be formed on the redistribution layer 300, and may cover the plurality of sub-semiconductor chips 700. After the formation of the mold layer 780, the carrier substrate 400 and the adhesion layer 410 may be removed. The removal of the carrier substrate 400 and the adhesion layer 410 may expose a lower conductive layer 116L of the preliminary substrate 101.

The lower conductive layer 116L may be patterned to form lower wiring patterns 116, and a mask layer 111 may be formed on a wiring dielectric layer 110 of the preliminary substrate 101 so as to cover the lower wiring patterns 116. As the lower wiring patterns 116 and the mask layer 111 are formed, a substrate 100 may be formed.

Lower connection bumps 130 may be correspondingly formed on the lower wiring patterns 116.

A cutting process may be performed on the substrate 100, the redistribution layer 300, and the mold layer 780, and therefore a semiconductor package 1400 may be fabricated as shown in FIG. 14.

According to some example embodiments, the preliminary substrate 101 having a wafer or panel shape may be formed on the carrier substrate 400 having a wafer or panel shape, and the preliminary substrate 101 may be provided therewith an upper structure (e.g., the redistribution layer 300, the plurality of sub-semiconductor chips 700, and the mold layer 780). In this case, the carrier substrate 400 and the preliminary substrate 101 each having a wafer or panel shape may be used to easily form the redistribution layer 300 and to effortlessly perform a grinding process on the top surface 700U of each of the plurality of sub-semiconductor chips 700. In addition, a wafer-level or panel-level package process may be available by using the carrier substrate 400 and the preliminary substrate 101 each having a wafer or panel shape.

Accordingly, it may be possible to provide a semiconductor package and its fabrication method capable of being easily fabricated and compatible with a wafer-level package and/or a panel-level package process.

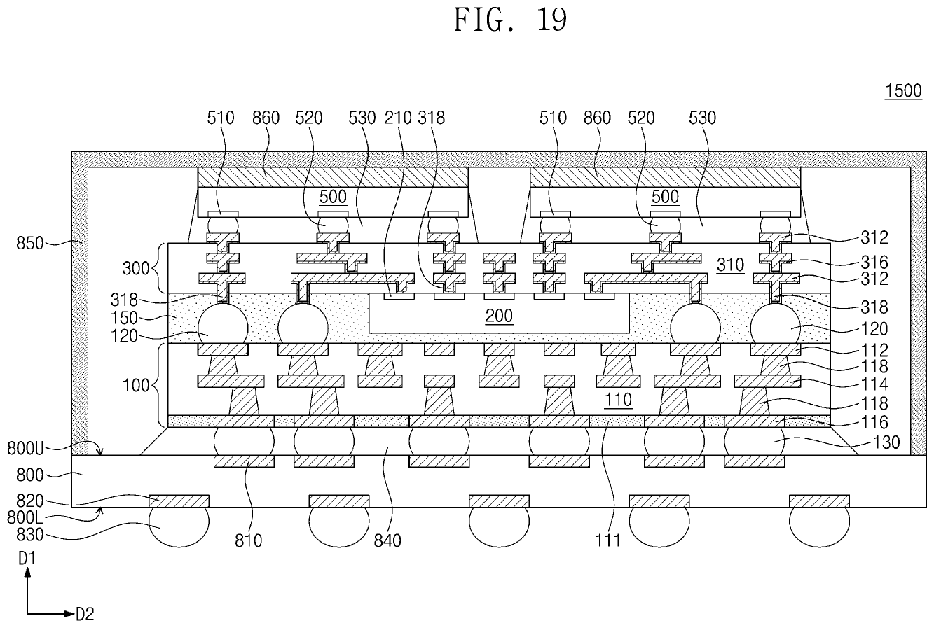

FIG. 19 illustrates a cross-sectional view showing a semiconductor package according to some example embodiments of the disclosure.

Referring to FIG. 19, a semiconductor package 1500 may further include a lower substrate 800 and a thermal radiation structure 850 on the lower substrate 800. The components of the semiconductor packages 1100, 1200, 1300, and 1400 discussed with reference to FIGS. 9, 12, 13, and 14 may be provided on the lower substrate 800 and in the thermal radiation structure 850. FIG. 19 depicts that the components of the semiconductor packages 1100 are provided on the lower substrate 800 and in the thermal radiation structure 850, but the disclosure are not limited thereto. The components of the semiconductor packages 1200, 1300, and 1400 discussed with reference to FIGS. 12, 13, and 14 may be provided on the lower substrate 800 and in the thermal radiation structure 850.

The lower substrate 800 may include first lower substrate pads 810 adjacent to a top surface 800U of the lower substrate 800 and second lower substrate pads 820 adjacent to a bottom surface 800L of the lower substrate 800. The first lower substrate pads 810 may be electrically connected to the second lower substrate pads 820 through internal lines in the lower substrate 800. The first and second lower substrate pads 810 and 820 may include a conductive material (e.g., metal). Bumps 830 may be provided on the bottom surface 800L of the lower substrate 800, and may be correspondingly connected to the second lower substrate pads 820. The bumps 830 may include a conductive material and may have at least one selected from solder-ball shapes, bump shapes, and pillar shapes. The lower substrate 800 may be, for example, a printed circuit board, a semiconductor chip, or a semiconductor package.

The substrate 100 may be provided on the top surface 800U of the lower substrate 800. The lower connection bumps 130 may be connected to the first lower substrate pads 810 of the lower substrate 800. The substrate 100 may be electrically connected to the lower substrate 800 through the lower connection bumps 130 and the first lower substrate pads 810.

A lower under-fill layer 840 may be provided between the substrate 100 and the lower substrate 800, and may cover the lower connection bumps 130. The lower under-fill layer 840 may include a dielectric polymeric material, such as an epoxy resin.

The thermal radiation structure 850 may be provided on the top surface 800U of the lower substrate 800, and may cover the components of the semiconductor packages 1100, 1200, 1300, and 1400 discussed with reference to FIGS. 9, 12, 13, and 14. The thermal radiation structure 850 may include a thermal conductive material. The thermally conductive material may include a metallic material or a carbon-containing material. According to an example embodiment, the metallic material may include, but is not limited to, copper and/or aluminum, and the carbon-containing material may include, but is not limited to graphene, graphite, and/or carbon nano-tube). For example, the thermal radiation structure 850 may include a single metal layer or a plurality of stacked metal layers. For another example, the thermal radiation structure 850 may include a heat sink or a heat pipe. For another example, the thermal radiation structure 850 may be configured to use water cooling.

The semiconductor package 1500 may further include a thermal conductive layer 860 interposed between the first upper semiconductor chip 500 and the thermal radiation structure 850. FIG. 19 depicts by way of example that the thermal conductive layer 860, but the disclosure are not limited thereto. The thermal conductive layer 860 may be interposed between the thermal radiation structure 850 and the upper semiconductor package 600 discussed with reference to FIGS. 12 and 13, or between the thermal radiation structure 850 and an uppermost one of the plurality of sub-semiconductor chips 700 discussed with reference to FIG. 14. The thermal conductive layer 860 may include a thermal interface material (TIM). The thermal interface material may include, for example, a polymer and thermal conductive particles. The thermal conductive particles may be dispersed in the polymer. Heat generated from the first upper semiconductor chip 500 may be transmitted through the thermal conductive layer 860 to the thermal radiation structure 850.

According to the disclosure, a preliminary substrate (e.g., an integrated circuit board) having a wafer or panel shape may be formed on a carrier substrate having a wafer or panel shape, and an upper structure (e.g., a redistribution layer and/or semiconductor chips) may be formed on the preliminary substrate. In this case, a wafer-level or panel-level package process may be available by using the carrier substrate and the preliminary substrate each having a wafer or panel shape, and a semiconductor package fabrication process may be simplified and reduced in cost by forming the upper structure on the preliminary substrate having a wafer or panel shape.

Accordingly, there may be a provided a semiconductor package and its fabrication method capable of being compatible with a wafer-level or panel-level package process, of simplifying fabrication process, and of reducing fabrication cost.

The aforementioned description provides some example embodiments for explaining the disclosure. Therefore, the disclosure are not limited to the embodiments described above, and it will be understood by one of ordinary skill in the art that variations in form and detail may be made therein without departing from the spirit and essential features of the disclosure.

1. A semiconductor package, comprising:
a substrate having a first surface and a second surface that are opposite to each other;
a redistribution layer provided on the first surface of the substrate, the redistribution layer having a third surface and a fourth surface that are opposite to each other, the third surface of the redistribution layer facing the first surface of the substrate;
a semiconductor chip provided between the substrate and the redistribution layer, the semiconductor chip being spaced apart from the first surface of the substrate and electrically connected to the third surface of the redistribution layer;
a connection structure provided between the substrate and the redistribution layer and horizontally spaced apart from the semiconductor chip, the connection structure being configured to electrically connect the substrate and the redistribution layer; and
a first dielectric layer provided between the substrate and the redistribution layer,
wherein the semiconductor chip and the connection structure are provided in the first dielectric layer.

2. The semiconductor package of claim 1, wherein the substrate is a printed circuit board.

3. The semiconductor package of claim 2, wherein
the substrate comprises a second dielectric layer and a plurality of upper wiring patterns buried in the second dielectric layer, the plurality of upper wiring patterns being adjacent to the first surface of the substrate, and
the connection structure is connected to a first upper wiring pattern among the plurality of upper wiring patterns.

4. The semiconductor package of claim 3, wherein the substrate further comprises:
a plurality of lower wiring patterns provided on the second dielectric layer and adjacent to the second surface of the substrate; and
a plurality of intermediate wiring patterns in the second dielectric layer, the plurality of intermediate wiring patterns configured to electrically connect the plurality of upper wiring patterns and the plurality of lower wiring patterns.

5. The semiconductor package of claim 4, wherein the substrate further comprises a mask layer adjacent to the second surface of the substrate, and adjacent to the plurality of lower wiring patterns.

6. The semiconductor package of claim 1, wherein
the redistribution layer comprises a third dielectric layer, a plurality of redistribution patterns in the third dielectric layer, and a plurality of redistribution vias in the third dielectric layer, the plurality of redistribution vias being connected to the redistribution patterns, and
at least one of the redistribution vias penetrates a portion of the first dielectric layer and is connected to the connection structure.

7. The semiconductor package of claim 6, wherein
the semiconductor chip comprises a plurality of chip pads adjacent to a top surface of the semiconductor chip,
the top surface of the semiconductor chip faces the third surface of the redistribution layer, and
the chip pads are connected to corresponding ones of the redistribution vias.

8. The semiconductor package of claim 7, wherein
the redistribution layer further comprises a plurality of seed patterns provided on bottom surfaces of the redistribution patterns, the seed patterns extending onto lateral surfaces and bottom surfaces of the redistribution vias,
the chip pads of the semiconductor chip are in direct contact with corresponding ones of the seed patterns, and
the corresponding ones of the seed patterns are in direct contact with the chip pads and the corresponding redistribution vias.

9. The semiconductor package of claim 1, wherein the first dielectric layer comprising a dielectric film comprising a thermosetting resin.

10. The semiconductor package of claim 1, wherein a lateral surface of the substrate is exposed without being covered with the first dielectric layer.

11. The semiconductor package of claim 1, wherein a lateral surface of the substrate, a lateral surface of the first dielectric layer, and a lateral surface of the redistribution layer are aligned with each other along a direction perpendicular to the first surface of the substrate.

12. The semiconductor package of claim 1, wherein the semiconductor chip is configured to electrically connect to the substrate through the redistribution layer and the connection structure.

13. The semiconductor package of claim 1, further comprising at least one first upper semiconductor chip on the fourth surface of the redistribution layer,
wherein the at least one first upper semiconductor chip is configured to electrically connect to the fourth surface of the redistribution layer.

14. The semiconductor package of claim 13, wherein
the redistribution layer comprises a third dielectric layer and a plurality of redistribution patterns in or on the third dielectric layer,
the at least one first upper semiconductor chip comprises a plurality of first upper chip pads,
the plurality of first upper chip pads are configured to electrically connect to first redistribution patterns, among the plurality of redistribution patterns, and
the first redistribution patterns are adjacent to the fourth surface of the redistribution layer.

15. The semiconductor package of claim 13, further comprising:
an upper semiconductor package provided on the fourth surface of the redistribution layer; and
a plurality of connection bumps between the redistribution layer and the upper semiconductor package,
wherein the connection bumps and the at least one first upper semiconductor chip are horizontally spaced apart from each other between the redistribution layer and the upper semiconductor package,
wherein the connection bumps are configured to electrically connect the upper semiconductor package and the redistribution layer.

16. The semiconductor package of claim 15, wherein the upper semiconductor package comprises;
an upper substrate;
at least one second upper semiconductor chip provided on the upper substrate; and
an upper mold layer provided on the upper substrate and the at least one second upper semiconductor chip,
wherein the connection bumps are configured to electrically connect to substrate pads of the upper substrate.

17. The semiconductor package of claim 1, further comprising:
an upper semiconductor package provided on the fourth surface of the redistribution layer; and
a plurality of connection bumps between the redistribution layer and the upper semiconductor package,
wherein the connection bumps are configured to electrically connect the upper semiconductor package and the redistribution layer.

18. A semiconductor package comprising:
a substrate comprising a first surface and a second surface that are opposite to each other;
a redistribution layer provided on the first surface of the substrate, the redistribution layer having a third surface and a fourth surface that are opposite to each other, the third surface of the redistribution layer facing the first surface of the substrate; and
at least one sub-semiconductor chip provided on the fourth surface of the redistribution layer,
wherein the substrate is a printed circuit board, and
wherein the substrate comprises:
a wiring dielectric layer;
a plurality of upper wiring patterns in the wiring dielectric layer and adjacent to the first surface of the substrate;
a plurality of lower wiring patterns on the wiring dielectric layer and adjacent to the second surface of the substrate; and
a mask layer adjacent to the second surface of the substrate and adjacent to the plurality of lower wiring patterns.

19. The semiconductor package of claim 18, wherein
the redistribution layer comprises:
a redistribution dielectric layer,
a plurality of redistribution patterns provided in the redistribution dielectric layer, and
a plurality of redistribution vias provided in the redistribution dielectric layer and connected to the redistribution patterns, and
wherein first redistribution vias, among the plurality of redistribution vias, are connected to the plurality of upper wiring patterns of the substrate.

20. (canceled)

21. A semiconductor package, comprising:
a substrate;
a redistribution layer provided on the substrate;
a dielectric layer provided between the substrate and the redistribution layer, and comprising:
a semiconductor chip;
a plurality of connection structures spaced apart from each other, and from the semiconductor chip, the plurality of connection structures being configured to electrically connect the substrate and the redistribution layer.

22-23. (canceled)
